(19) United States
(12) Patent Application Publication
(10) Pub. No.: US 2007/0181529 A1
(43) Pub. Date: Aug. 9, 2007

(54) Corona discharge plasma source devices, and various systems and methods of using same

(76) Inventor: Krupakar Murali Subramanian, Boise, ID (US)

Correspondence Address: WILLIAMS, MORGAN & AMERSON, 10333 RICHMOND, SUITE 1100, HOUSTON, TX, 77042, US

(21) Appl. No.: 11/349,005

(22) Filed: Feb. 7, 2006

(51) Int. Cl. C23F 1/00; H01L 21/461; H01L 21/302; H01L 21/306

(52) U.S. Cl. 216/67; 438/706; 156/345.1; 438/710

(57) ABSTRACT

The present invention is generally directed to corona discharge plasma source devices, and various systems and methods for using same. In one illustrative embodiment, the system comprises a process chamber, a support member comprising a plurality of tapered conductive members positioned in the member and a power supply system for applying at least one voltage level to the plurality of tapered conductive members.

### BACKGROUND OF THE INVENTION

1. Field of the Invention

The present invention is generally related to the field of plasma-based processing, and, more particularly, to corona discharge plasma source (CDPS) devices, and various systems and methods of using same.

2. Description of the Related Art

Plasma-based processing techniques are very common in many industries. For example, in the manufacture of integrated circuit devices, plasma-based etching and deposition processes are frequently employed. Additionally, ions of a certain dopant species are frequently implanted at desired locations on a semiconducting substrate to form various structures.

Generating and controlling the ions employed in such processes is a very complex undertaking. Precise control of the ion generation process, energy levels and placement of the ions is imperative in modem semiconductor manufacturing due to the very small feature sizes of modem integrated circuit devices. Moreover, better control of such processes may enhance product yield. As device dimensions continue to shrink, it becomes even more important to be able to reliably form very thin layers of material. One common process used to form very thin layers of material is known as an atomic layer deposition (ALD) process. While effective at forming very thin layers of material, the ALD process is very slow, thereby reducing manufacturing productivity.

The present invention is directed to various systems and methods that may solve, or at least reduce, some or all of the aforementioned problems.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

The present invention is generally directed to corona discharge plasma source devices, and various systems and methods of using same. In one illustrative embodiment, the system comprises a process chamber, a support member comprising a plurality of tapered conductive members positioned in the member and a power supply system for applying at least one voltage level to the plurality of tapered conductive members.

### BRIEF DESCRIPTION OF THE DRAWINGS

The invention may be understood by reference to the following description taken in conjunction with the accompanying drawings, in which like reference numerals identify like elements, and in which:

FIGS. 1 and 2 depict illustrative embodiments of systems employing a CDPS device in accordance with one illustrative embodiment of the present invention;

FIGS. 3A-3B depict one illustrative example of a CDPS device in accordance with the present invention;

FIGS. 4A-4B depict an illustrative example of a CDPS device in accordance with the present invention;

FIGS. 5A-5B depict yet another illustrative example of a CDPS device in accordance with the present invention;

FIGS. 6A-6B are enlarged views of illustrative examples of CDPS devices in accordance with one embodiment of the present invention; and

FIG. 7 is a schematic view of an illustrative CDPS device in accordance with one aspect of the present invention.

While the invention is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF THE INVENTION

Illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present invention will now be described with reference to the attached figures. Although the various regions and structures are depicted in the drawings as having very precise, sharp configurations and profiles, those skilled in the art recognize that, in reality, these regions and structures may not be as precise as indicated in the drawings. Additionally, the relative sizes of the various features and structures depicted in the drawings may be exaggerated or reduced as compared to the actual size of those features or structures. Nevertheless, the attached drawings are included to describe and explain illustrative examples of the present invention. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

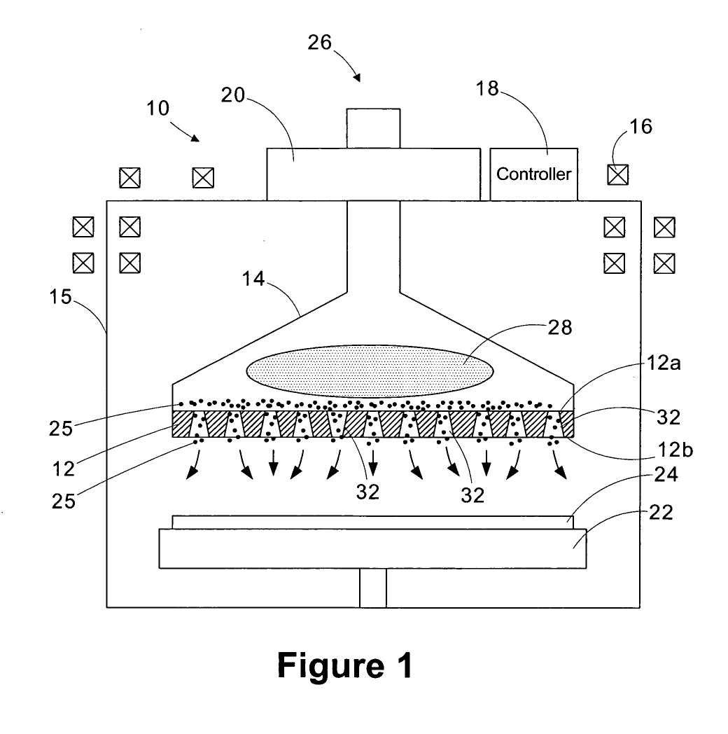

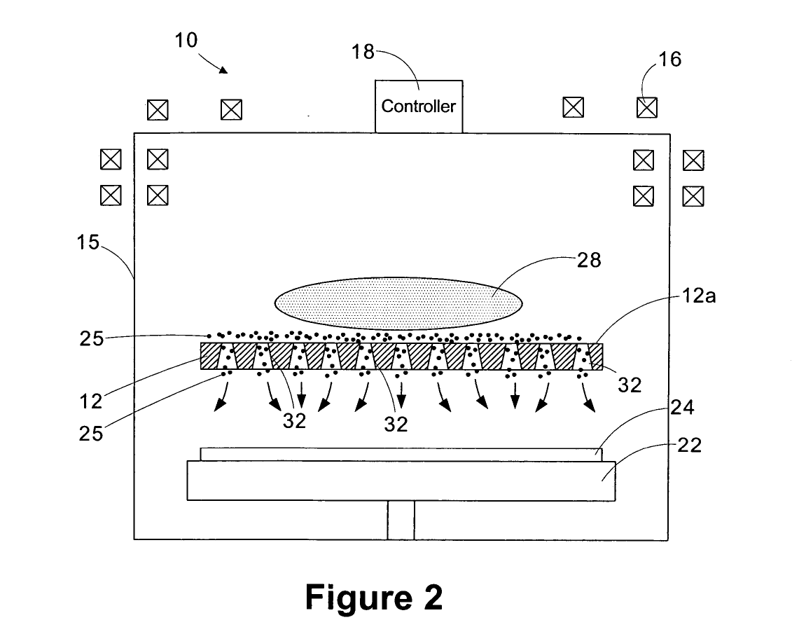

FIG. 1 is a schematic depiction of one illustrative embodiment of a system 10 employing a plurality of tapered conductive members 32 that function as corona discharge plasma source (CDPS) devices in accordance with the present invention. As shown more fully therein, the system 10 comprises a support member 12, e.g., a plate, a cover 14, a plurality of coils 16, a controller 18, a mechanical movement assembly 20 and a wafer stage or chuck 22. FIG. 2 is an illustrative alternative embodiment of the system 10 wherein the cover 14 is not provided. In FIG. 1, an illustrative plasma 28 is depicted as being generated within the cover 14 behind the support member 12. Various process gases may be introduced within the cover 14 via the inlet 26. A plasma 28 may also be generated within the chamber 15 in the embodiment depicted in FIG. 2. If desired, a plurality of openings (not shown) may be provided in the sides of the cover 14 to facilitate an exchange with the process gases within the chamber 15.

In general, the systems shown in FIGS. 1 and 2 will be used to generate active neutrals and ions that may be employed in plasma processing operations, as described more fully below. The mechanical movement assembly 20 may be provided to raise, lower and/or rotate the support member 12 before or during operations. The mechanical movement assembly 20 may comprise a variety of mechanical and electromechanical devices for moving the support member 12, e.g., gears, motors, lever arms, etc. Such devices are well known to those skilled in the art and, thus, will not be discussed in any further detail so as not to obscure the present invention. Likewise, the support member 12 may be movably secured or mounted within the chamber 15 using a variety of known mechanical systems and devices.

An illustrative semiconducting substrate 24 is positioned on the stage 22. The substrate 24 may be made of a variety of semiconductor materials, e.g., silicon, silicon germanium, GaNᵢ, GaAs, SiC, etc., and it may be doped or undoped depending on the particular application. Additionally, the substrate 24 may have one or more features formed above or in the substrate 24.

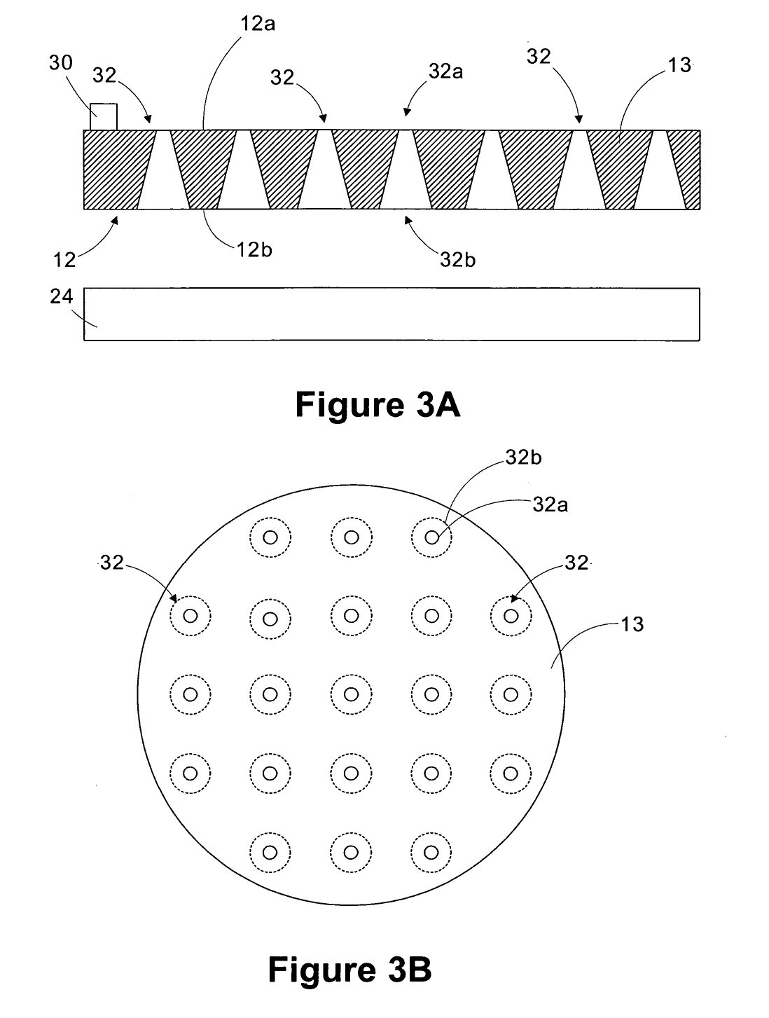

As shown in FIGS. 3A-3B, the support member 12 comprises a plurality of CDPS devices 32 positioned therein that are used in generating the active neutrals and ions. The CDPS devices 32 have an inlet 32a and an outlet 32b. Of course, the embodiments depicted in FIGS. 3A-3B are enlarged for purposes of explanation. In an actual embodiment, there may be hundreds or thousands of the CDPS devices 32 formed in the support member 12. Thus, the illustrative examples described herein should not be considered a limitation of the present invention. Moreover, the support member 12 may be larger or smaller than the substrate 22 in terms of size, and it may have any desired shape or configuration. In the disclosed embodiment, the inlet 32a is positioned proximate a front surface 12a of the member 12, whereas the outlet 32b is positioned proximate the back surface 12b of the member 12.

The CDPS devices 32 may be positioned in the support member 12 in a random or ordered fashion. FIG. 3B depicts an illustrative example wherein the CDPS devices 32 are arranged in an ordered pattern. Of course, such an arrangement is provided by way of example only.

As indicated previously, the CDPS devices 32 may be made of a variety of conductive materials. The CDPS devices 32 may be formed or positioned in a substrate 13 that is part of or constitutes the support member 12. The substrate 13 may be comprised of a variety of insulating materials, e.g., silicon dioxide or silicon oxynitride. In some cases, the substrate 13 may be comprised of silicon. Alternatively, the substrate 13 may be comprised of a non-insulating, conductive material, and the individual CDPS devices 32 may be electrically isolated from the substrate 13 by an insulating material or layer (not shown) formed or positioned between the CDPS devices 32 and the substrate 13. As yet another alternative, when the support member 12 is comprised of a conductive material, all of the CDPS devices 32 may be conductively coupled to the support member 12.

The system 10 may further comprise schematically depicted associated control circuitry 30 (see FIG. 3A) for controlling various operational aspects of the CDPS devices 32, as will be described more fully below. More specifically, the control circuitry 30 and the controller 18 may be used to regulate and control a voltage (Ve) applied to the CDPS devices 32 from a voltage source (not shown). As set forth above, the CDPS devices 32 have an inlet opening 32a and an outlet opening 32b. In operation, the CDPS devices 32 will be used to generate and control the distribution of schematically depicted active neutrals and ions 25, which will ultimately pass through the CDPS devices 32 and impact the substrate 24.

In the illustrative embodiment depicted in FIGS. 3A-3B, the CDPS devices 3232 have a generally conical configuration. Of course, the description of the CDPS devices 32 as having a conical configuration is intended only to provide an introductory explanation of differing embodiments of the present invention. Thus, such descriptions should not be considered a limitation of the present invention.

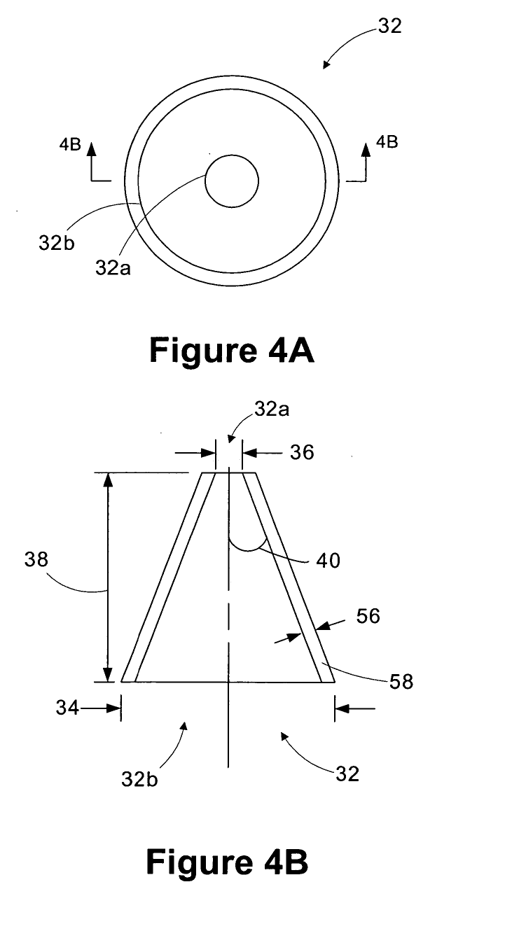

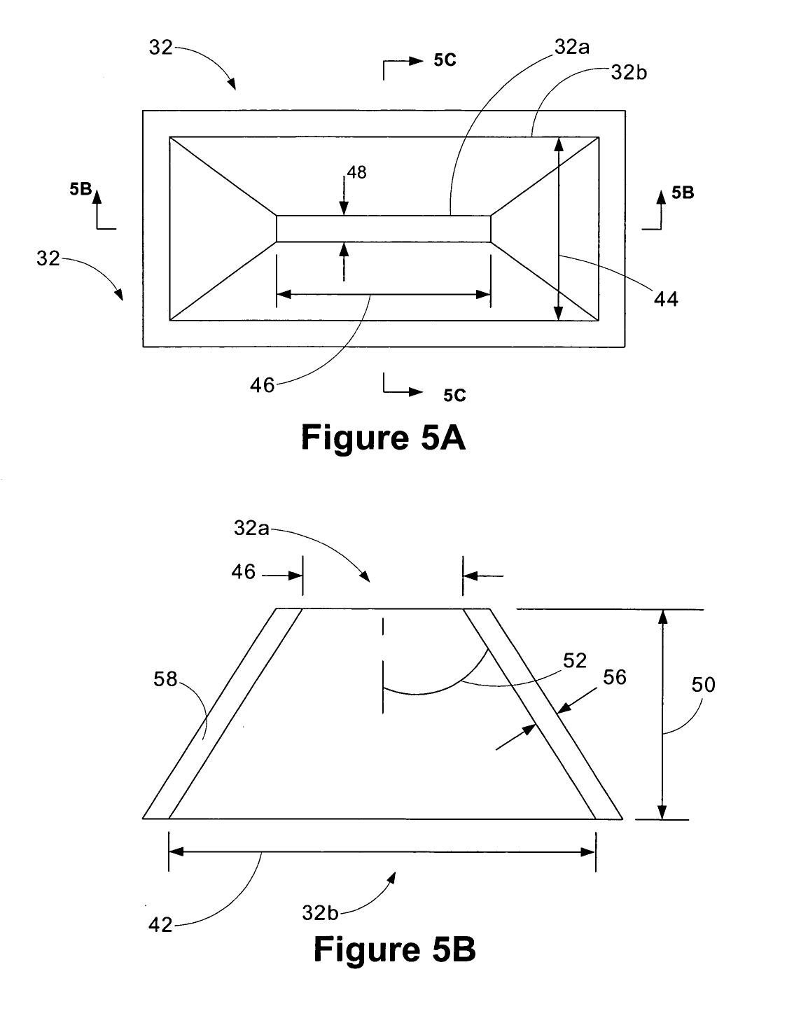

FIGS. 4A-4B and 5A-5C disclose various illustrative examples of a CDPS device 32 in accordance with illustrative aspects of the present invention. In FIGS. 4A-4B, the illustrative CDPS device 32 has a generally conical configuration and it has an inlet 32a and an outlet 32b. FIG. 4A is a bottom view of the illustrative CDPS device 32. In the embodiment depicted in FIGS. 4A-4B, the inlet 32a and outlet 32b have a generally circular configuration. In general, the inlets 32a of the various CDPS devices 32 disclosed herein is very small, e.g., on the order of approximately several micrometers, whereas the outlet 32b is relatively much larger, e.g., on the order of tens of micrometers. In some embodiments, the area ratio between the outlet 32b and the inlet 32a may range from some number greater than 1, up to a relatively large number, e.g., 10,000 or more. In the illustrative example depicted in FIGS. 4A-4B, the illustrative circular inlet 32a has a diameter 36 of approximately 0.1-90 μm while the illustrative circular outlet 32b has a diameter 34 of approximately 10-1000 μm. The CDPS device 32 depicted in FIGS. 4A-4B also has a length 38 that may vary depending upon the particular application. For example, the length 38 of the CDPS device 32 may range from approximately 100-1000 μm. Similarly, the CDPS device 32 depicted in FIGS. 4A-4B may further be defined by the angle 40, which also may vary depending upon the particular application. In one illustrative example, the angle 40 may vary from approximately 5-85 degrees. In general, the ratio of the outlet area to the inlet area may be in the range of approximately 2-2000. In the depicted embodiment, the CDPS devices 32 are depicted wherein the inlet is smaller than the outlet. However, in some embodiments, the inlet may be larger than the outlet, i.e., the CDPS device may be inverted. Thus, the illustrative depiction of the CDPS devices disclosed herein should not be considered a limitation of the present invention.

The CDPS device 32 depicted in FIGS. 5A-5C has a generally tapered, rectangular configuration. FIG. 5A is a bottom view of the illustrative CDPS device 32. As shown therein, the CDPS device 32 has an inlet 32a and an outlet 32b. In the embodiment depicted in FIGS. 5A-5C, both the inlet 32a and the outlet 32b are generally rectangular-shaped openings. The inlet 32a of the CDPS device 32 depicted in FIGS. 5A-5C may have a length 46 of approximately 1-20,000 μm and a width 48 of approximately 0.1-20 μm. The outlet 32b may have a length 42 of approximately 100-2000 μm and a width 48 of approximately 10-200 μm. The length or depth 50 of the CDPS device 32 depicted in FIGS. 5A-5C may be approximately the same as that described for the embodiment depicted in FIGS. 4A-4B. As indicated in FIGS. 5B-5C, the CDPS device 32 depicted herein may further be defined by two angles 52, 54, each of which may vary depending upon the particular application. The surfaces of the inlets 32a and the outlets 32b of the CDPS devices 32 disclosed herein may be either substantially flat or curved depending on the particular application.

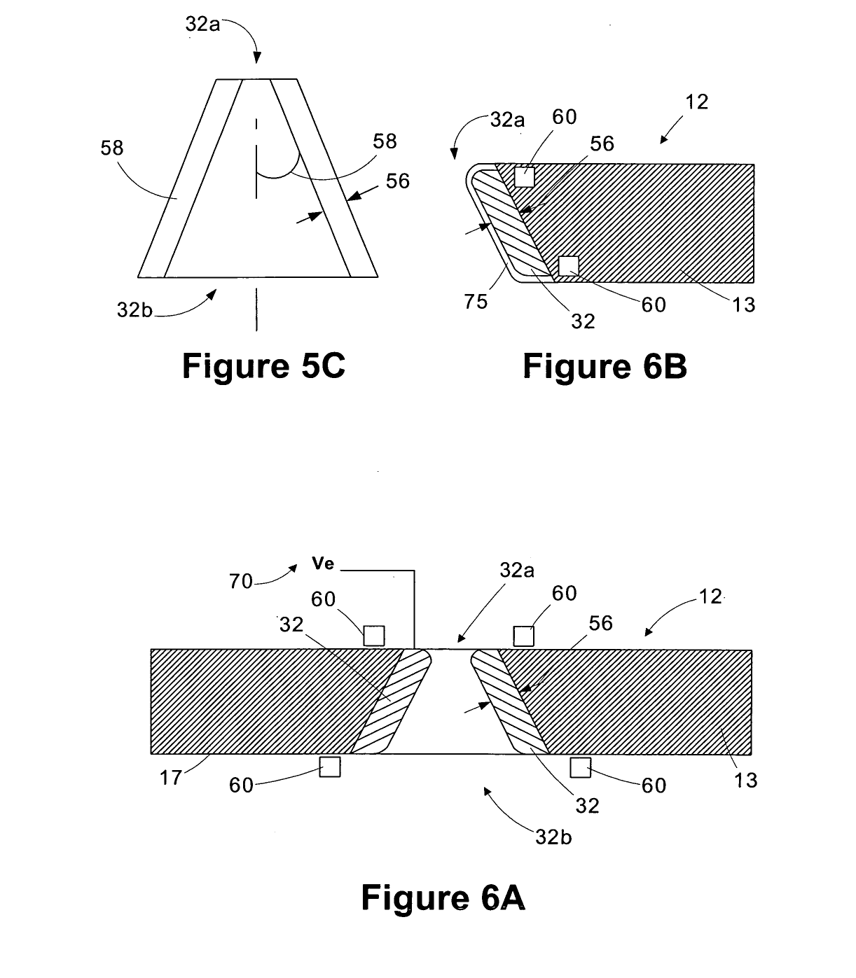

The CDPS device 32 may be comprised of a variety of different conductive materials, e.g., a metal, doped polysilicon, etc. The thickness 56 of the CDPS device 32 may also vary depending on the particular application. In one illustrative embodiment, the thickness 56 of the CDPS device 32 may be on the order of approximately 100-200 Å. As depicted in FIG. 6A, a voltage 70 (Ve) may be applied to the CDPS device 32 for purposes to be more fully described below.

Also depicted in FIG. 6A are a plurality of energizing coils 60 positioned adjacent the surface 17 of the substrate 13 near the CDPS device 32. The coils 60 may be positioned adjacent the surface 17 of the substrate 13 or embedded within the substrate 13, as illustratively depicted in FIG. 6B. The energizing coils 60 adjacent the inlet 32a of the devices 32 may be considered to be inlet energizing coils, whereas the energizing coils 60 positioned adjacent the outlet 32b may be considered to be outlet energizing coils. If desired, an illustrative layer of insulating material 75 (see FIG. 6B) may be formed to insulate the surface of the CDPS device 32.

As will be described more fully below, the coils 60 may be employed to generate a magnetic field that may be used to control various operational aspects of the CDPS device 32. The number, size and placement of the coils 60 may vary depending on the particular application. In general, the size and placement of the coils 60 should be such that the magnetic field produced by energizing the coils 60 can accomplish the purposes described herein. In one particularly illustrative embodiment, the coils 60 are single turn coils comprised of a single wire having a diameter of approximately 1 micron. Note that the coils 60 need not be provided adjacent both the inlet and outlet of the device 32 in all applications. Thus, the depicted embodiments should not be considered a limitation of the present invention.

As described previously, the systems 10 may be provided with schematically depicted control/power circuitry 30, as shown in FIG. 3A. Each of the depicted CDPS devices 32 is electrically coupled to the control/power circuitry 30. The control/power circuitry 30 may be employed in controlling the operational characteristics of the CDPS devices 32. Of course, the control/power circuitry 30 need not be physically located on the support member 12, and it may be positioned at any desired location.

The controller 18 may be used to control various operational aspects of the system 10, such as the generation and control of the plasma 28 and the operation of the CDPS devices 32. The plasma 28 may be generated in accordance with known techniques and processes. If desired, relative movement (rotational and/or translational) between the support member 12 and the substrate 24 may be provided via known mechanical systems (not shown) that are provided within the mechanical movement assembly 20. Such movements may be controlled by the controller 18.

In general, each of the individual CDPS devices 32 in the support member 12 may be independently controlled through use of the controller 18 and the control/power circuitry 30. More specifically, appropriate voltage levels (Ve) may be applied to each of the individual CDPS devices 32 to generate the necessary electrical field to generate the ions and/or neutral particles 25. Of course, if desired, the applied voltage (Ve) need not be the same for all of the CDPS devices 32. Different voltage levels may be applied to devices depending upon their group location on the support member 12, e.g., devices 32 in the center region of the support member 12 may receive higher voltages than devices 32 located away from the center region. The appropriate voltage to be applied to the individual CDPS devices 32 can be calculated or determined based upon process requirements. The controller 18 and the associated control/power circuitry 30 may then be used to apply the desired voltage to each of the individual CDPS devices 32 on the support member 12.

When the voltage (Ve) is applied to the CDPS device 32, there is an enhancement of the electric field proximate the entrance 32a. A plasma may also be generated proximate the entrance 32a. Due to this enhancement, a corona discharge occurs in the area or region adjacent the entrance 32a of the CDPS device 32. This high field gradient causes the process gas molecules adjacent the entrance 32a to split. The resulting ions and neutrals 25 fall through the CDPS device 32. Process gases may be provided to the backside of the support member 12 via the cover 14. Alternatively, as depicted in FIG. 2, the process gases within the chamber 15 may also be split using the present invention.

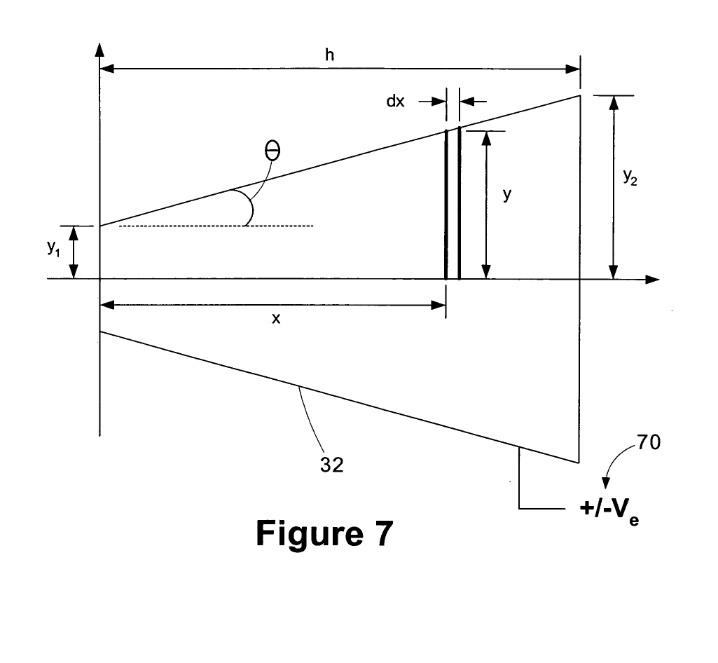

More specifically, FIG. 7 depicts an illustrative geometry for a CDPS device 32 in accordance with one illustrative embodiment of the present invention. A voltage (±V) may be applied to the conductive CDPS for various purposes to be described more fully below. Since the potential V=E×d, where E is the electric field and d is the perpendicular distance from the source, the field gradient between any two points within the CDPS device 32 is given by:

$$Δ E = V ( \frac{1}{{y}_{1}} - \frac{1}{y} ) = V ( \frac{y - {y}_{1}}{y \cdot {y}_{1}} )$$

$$tan θ = \frac{y - {y}_{1}}{x} ⇒ y = {y}_{1} + x tan θ$$

$$Hence Δ E = V ( \frac{{y}_{1} + tan θ - {y}_{1}}{( {y}_{1} + x tan θ ) \cdot {y}_{1}} ) = V ( \frac{x tan θ}{{y}_{1}^{2} + x \cdot {y}_{1} tan θ} )$$

Since y₁ is of the order of ˜100 nm, y₁² is a very small quantity and may be neglected.

$$∴ Δ E = \frac{V}{{y}_{1}} or simply \frac{ⅆ E}{ⅆ x} = \frac{V}{{y}_{1}}$$

Hence, by applying just 1 V to the CDPS device 32, we get an E-field gradient of around 10⁷ V/m. An ion falling through this field gradient picks up an energy equivalent to this voltage expressed in the units of eV. However, when a neutral moves into the vicinity of this field gradient, it is spontaneously ionized. If a neutral molecule moves into this field gradient, it is split into smaller constituents that are generally more reactive than the parent molecule.

In one illustrative embodiment, each of the CDPS devices 32 may be individually turned on/off using external computer control, such as the illustrative controller 18. To turn the CDPS devices 32 “ON,” if there is no plasma 28 generated, a negative (with respect to the walls of the chamber 15) voltage (Ve) is applied to the CDPS devices 32. If a plasma 28 has been generated, then the negative voltage applied is with respect to the voltage of the plasma 28. The magnitude of the applied voltage Ve may vary depending upon the particular application. In one illustrative embodiment, the magnitude may range from approximately 0.1-100 volts. If desired, the support member 12 may be rotated during the process to even out the distribution of the ions/neutrals flux via the support member 12. The number of active species (ions or neutrals) delivered to the substrate 24 may vary depending on a number of factors, e.g., the relative distance between the support member 12 and the substrate 24.

The CDPS devices 32 each act as corona discharge sources that split the molecules of the adjacent process gases into active neutrals (e.g., steam H₂O into OH, O, H, etc.) and ions (e.g., H₂O into OH⁻, O⁺, etc.). The magnetic field generated by the coils 60 placed around the entrance 32a and exit 32b of the CDPS devices 32 guide the generated ions toward the substrate 24, but they do not affect the neutrals. The neutrals move downward through the CDPS devices 32 via their own inertia and momentum.

The system 10 disclosed herein may be used for many purposes within the semiconductor fabrication industry. For example, the present invention may be employed in performing plasma enhanced deposition or etching processes. As a specific illustrative example, the CDPS devices 32 could be used in addition to, or in lieu of, a traditional plasma source in a plasma enhanced atomic layer deposition (PEALD) process.

The present invention is generally directed to corona discharge plasma source devices, and various systems and methods of using same. In one illustrative embodiment, the system comprises a process chamber, a support member comprising a plurality of tapered conductive members positioned in the member and a power supply system for applying at least one voltage level to the plurality of tapered conductive members.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A system, comprising:
a process chamber;
a support member comprising a plurality of tapered conductive members positioned in said support member; and
a power supply system for applying at least one voltage level to said plurality of tapered conductive members.

2. The system of claim 1, wherein said support member is a plate.

3. The system of claim 1, wherein said tapered conductive members have a conical configuration with a substantially circular inlet and a substantially circular outlet.

4. The system of claim 1, wherein said tapered conductive members have a tapered rectangular configuration with a substantially rectangular inlet and a substantially rectangular outlet.

5. The system of claim 1, wherein said plurality of tapered conductive members are positioned in said support member in an ordered pattern.

6. The system of claim 1, wherein said plurality of tapered conductive members are positioned in said support member in a non-ordered arrangement.

7. The system of claim 1, further comprising a cover that is adapted to direct process gases introduced into said system toward a front surface of said support member.

8. The system of claim 1, wherein each of said plurality of tapered conductive members have an inlet opening and an outlet opening, said inlet opening being smaller than said outlet opening, and wherein said inlet opening of said plurality of tapered conductive members is positioned adjacent a front surface of said support member.

9. The system of claim 1, further comprising an inlet energizing coil positioned adjacent an inlet opening of each of said tapered conductive members.

10. The system of claim 9, wherein said inlet energizing coil is embedded within said support member.

11. The system of claim 9, wherein said inlet energizing coil is positioned adjacent a front surface of said support member.

12. The system of claim 9, wherein said support member is comprised of a conductive material.

13. The system of claim 9, wherein said support member is comprised of a insulating material.

14. The system of claim 1, further comprising an outlet energizing coil positioned adjacent an outlet opening of each of said tapered conductive members.

15. The system of claim 14, wherein said outlet energizing coil is embedded within said support member.

16. The system of claim 14, wherein said outlet energizing coil is positioned adjacent a back surface of said support member.

17. The system of claim 1, further comprising a substrate support stage positioned beneath said support member.

18. A system, comprising:
a process chamber;
a support member comprising a plurality of tapered conductive members positioned in said support member, each of said tapered conductive members having an inlet opening defining an inlet area and an outlet opening defining an outlet area, wherein said outlet area is greater than said inlet area; and
a power supply system for applying at least one voltage level to said plurality of tapered conductive members.

19. The system of claim 18, wherein said tapered conductive members have a conical configuration with a substantially circular inlet and a substantially circular outlet.

20. The system of claim 18, wherein said tapered conductive members have a tapered rectangular configuration with a substantially rectangular inlet and a substantially rectangular outlet.

21. The system of claim 18, wherein said plurality of tapered conductive members are positioned in said support member in an ordered pattern.

22. The system of claim 18, wherein said plurality of tapered conductive members are positioned in said support member in a non-ordered arrangement.

23. The system of claim 18, further comprising a cover that is adapted to direct process gases introduced into said system toward a front surface of said support member.

24. The system of claim 18, wherein said inlet opening of each of said plurality of tapered conductive members is positioned adjacent a front surface of said support member.

25. The system of claim 18, wherein said outlet opening of each of said plurality of tapered conductive members is positioned adjacent a back surface of said support member.

26. The system of claim 18, further comprising an inlet energizing coil positioned adjacent an inlet opening of each of said tapered conductive members.

27. The system of claim 26, wherein said inlet energizing coil is embedded within said support member.

28. The system of claim 26, wherein said inlet energizing coil is positioned adjacent a front side surface of said support member.

29. The system of claim 26, wherein said support member is comprised of a conductive material.

30. The system of claim 26, wherein said support member is comprised of a insulating material.

31. The system of claim 18, further comprising an outlet energizing coil positioned adjacent an outlet opening of each of said tapered conductive members.

32. The system of claim 31, wherein said outlet energizing coil is embedded within said support member.

33. The system of claim 31, wherein said outlet energizing coil is positioned adjacent a backside surface of said support member.

34. The system of claim 18, further comprising a substrate support stage positioned beneath said support member.

35. A method, comprising:
positioning a semiconducting substrate in a system comprising a process chamber and a support member comprising a plurality of tapered conductive members positioned in said support member;
introducing a process gas into said processing chamber; and
applying at least one voltage level to said plurality of tapered conductive members to generate at least one of active neutrals and ions.

36. The method of claim 35, wherein applying at least one voltage level to said plurality of tapered conductive members to generate at least one of active neutrals and ions comprises applying different voltage levels to different tapered conductive members within said plurality of conductive members.

37. The method of claim 35, wherein applying at least one voltage level to said plurality of tapered conductive members to generate at least one of active neutrals and ions comprises applying the same voltage level to all of the tapered conductive members within said plurality of conductive members.

38. The method of claim 35, wherein applying at least one voltage level to said plurality of tapered conductive members to generate at least one of active neutrals and ions comprises applying the same voltage level to all tapered conductive members in said support member.

39. The method of claim 35, wherein said tapered conductive members have a conical configuration with a substantially circular inlet and a substantially circular outlet.

40. The method of claim 35, wherein said tapered conductive members have a tapered rectangular configuration with a substantially rectangular inlet and a substantially rectangular outlet.

41. The method of claim 35, wherein said plurality of tapered conductive members are positioned in said support member in an ordered pattern.

42. The method of claim 35, wherein said plurality of tapered conductive members are positioned in said support member in a non-ordered arrangement.

43. The method of claim 35, wherein said system further comprises a cover positioned proximate a front surface of said support member, and wherein introducing said process gas into said process chamber comprises introducing said process gas into at least said cover.

44. The method of claim 35, wherein introducing said process gas to said processing chamber comprises directing said process gas toward said inlets of said plurality of tapered conductive members.

45. The method of claim 35, further comprising energizing a coil positioned adjacent an inlet opening of each of said plurality of tapered conductive members.

46. The method of claim 35, further comprising energizing a coil positioned adjacent an outlet opening of each of said plurality of tapered conductive members.

47. A method, comprising:
positioning a semiconducting substrate in a system comprising a process chamber and a support member comprising a plurality of tapered conductive members positioned in said support member, each of said tapered conductive members having an inlet opening defining an inlet area and an outlet opening defining an outlet area, wherein said outlet area is greater than said inlet area;
introducing a process gas into said processing chamber; and
applying at least one voltage level to said plurality of tapered conductive members to generate at least one of active neutrals and ions.

48. The method of claim 47, wherein applying at least one voltage level to said plurality of tapered conductive members to generate at least one of active neutrals and ions comprises applying different voltage levels to different tapered conductive members within said plurality of conductive members.

49. The method of claim 47, wherein applying at least one voltage level to said plurality of tapered conductive members to generate at least one of active neutrals and ions comprises applying the same voltage level to all of the tapered conductive members within said plurality of conductive members.

50. The method of claim 47, wherein applying at least one voltage level to said plurality of tapered conductive members to generate at least one of active neutrals and ions comprises applying the same voltage level to all tapered conductive members in said support member.

51. The method of claim 47, wherein said tapered conductive members have a conical configuration with a substantially circular inlet and a substantially circular outlet.

52. The method of claim 47, wherein said tapered conductive members have a tapered rectangular configuration with a substantially rectangular inlet and a substantially rectangular outlet.

53. The method of claim 47, wherein said plurality of tapered conductive members are positioned in said support member in an ordered pattern.

54. The method of claim 47, wherein said plurality of tapered conductive members are positioned in said support member in a non-ordered arrangement.

55. The method of claim 47, wherein said system further comprises a cover positioned proximate a front surface of said support member, and wherein introducing said process gas into said process chamber comprises introducing said process gas into at least said cover.

56. The method of claim 47, wherein introducing said process gas into said processing chamber comprises directing said process gas toward said inlets of said plurality of tapered conductive members.

57. The method of claim 47, further comprising energizing a coil positioned adjacent an inlet opening of each of said plurality of tapered conductive members.

58. The method of claim 47, further comprising energizing a coil positioned adjacent an outlet opening of each of said plurality of tapered conductive members.
